(19) United States
(12) Patent Application Publication
(10) Pub. No.: US 2023/0377893 A1
(43) Pub. Date: Nov. 23, 2023

(54) METHOD FOR MANUFACTURING SEMICONDUCTOR DEVICE, AND DEVICE FOR MANUFACTURING SEMICONDUCTOR DEVICE

(71) Applicant: Tokyo Electron Limited, Tokyo (JP)

(72) Inventors: Shunji YAMAKAWA, Yamanashi (JP); Tadahiro ISHIZAKA, Yamanashi (JP); Masato SAKAMOTO, Yamanashi (JP); Kohichi SATOH, Yamanashi (JP)

(21) Appl. No.: 18/027,722

(22) PCT Filed: Sep. 15, 2021
(86) PCT No.: PCT/JP2021/033970

§ 371 Date: Mar. 22, 2023

(30) Foreign Application Priority Data
Sep. 29, 2020 (JP) 2020-163822

(51) Int. Cl. H01L 21/285; H01L 21/768; C23C 16/18

(52) U.S. Cl. CPC H01L 21/28568; H01L 21/76879; C23C 16/18

(57) ABSTRACT

A method for manufacturing a semiconductor device that includes forming a ruthenium film on a conductive film formed on a substrate for manufacture of the semiconductor device, wherein the conductive film includes a metal that increases an electrical resistance between the conductive film and the ruthenium film by interfacial diffusion between the conductive film and the ruthenium film, and wherein the method comprises forming the ruthenium film on the conductive film by alternately repeating a plurality of times: forming a ruthenium thin film by supplying a ruthenium raw material gas to the substrate on which the conductive film is formed; and then supplying a boron compound gas to the ruthenium thin film.

### TECHNICAL FIELD

The present disclosure relates to a method for manufacturing a semiconductor device and an apparatus for manufacturing a semiconductor device.

### BACKGROUND

In an operation of manufacturing a semiconductor device, a processing of forming a metal film on a semiconductor wafer (hereinafter referred to as a wafer), which is a substrate for the manufacture of the semiconductor device, is performed. A ruthenium (Ru) film may be formed as this metal film. Patent Document 1 discloses a processing of forming an Ru film as a barrier film in a recess, which has a sidewall formed by an SiCOH film and a bottom surface made of copper, and then burying copper serving as a conductive path. Further, it describes supplying a diborane (B₂H₆) gas in order to increase adhesion between the Ru film and the SiCOH film before the formation of the Ru film.

### PRIOR ART DOCUMENT

### Patent Document

Patent Document 1: Japanese Laid-Open Patent Publication No. 2013-175702

The present disclosure is to prevent an increase in the electrical resistance of a ruthenium film formed on a conductive film, which is formed on a substrate for the manufacture of a semiconductor device.

### SUMMARY

A method for manufacturing a semiconductor device according to the present disclosure includes forming a ruthenium film on a conductive film formed on a substrate for manufacture of the semiconductor device, wherein the conductive film includes a metal that increases an electrical resistance between the conductive film and the ruthenium film by interfacial diffusion between the conductive film and the ruthenium film, and wherein the method includes an operation of forming the ruthenium film on the conductive film by alternately repeating a plurality of times: forming a ruthenium thin film by supplying a ruthenium raw material gas to the substrate on which the conductive film is formed; and then supplying a boron compound gas to the ruthenium thin film.

According to the present disclosure, it is possible to prevent an increase in the electrical resistance of a ruthenium film formed on a conductive film of a substrate for the manufacture of a semiconductor device.

### BRIEF DESCRIPTION OF DRAWINGS

FIG. 1 is a cross-sectional view of a wafer from which a semiconductor device according to an embodiment of the present disclosure is manufactured.

FIG. 2 is an enlarged schematic diagram of the bottom of a via hole in which an Ru film is buried.

FIG. 3 is a manufacturing process diagram of a semiconductor device illustrating formation of an Ru film according to a comparative embodiment.

FIG. 4 is a manufacturing process diagram of a semiconductor device illustrating formation of an Ru film according to a comparative embodiment.

FIG. 5 is a manufacturing process diagram of a semiconductor device according to an embodiment of the present disclosure.

FIG. 6 is a manufacturing process diagram of a semiconductor device according to an embodiment of the present disclosure.

FIG. 7 is a manufacturing process diagram of a semiconductor device according to an embodiment of the present disclosure.

FIG. 8 is a longitudinal side view of an Ru film forming apparatus.

FIG. 9 is a graph illustrating atomic distribution in a depth direction of a wafer in Comparative Example 1;

FIG. 10 is a graph illustrating atomic distribution in a depth direction of a wafer in Example 1;

FIG. 11 is a graph illustrating distribution of Co and Ru in a depth direction of a wafer before annealing in Comparative Example 2;

FIG. 12 is a graph illustrating distribution of Co and Ru in the depth direction of the wafer after annealing in Comparative Example 2;

FIG. 13 is a graph illustrating distribution of Co and Ru in the depth direction of the wafer before annealing in Example 1.

FIG. 14 is a graph illustrating distribution of Co and Ru in the depth direction of the wafer after annealing in Example 1.

### DETAILED DESCRIPTION

### <Overview of Method of Manufacturing Semiconductor Device>

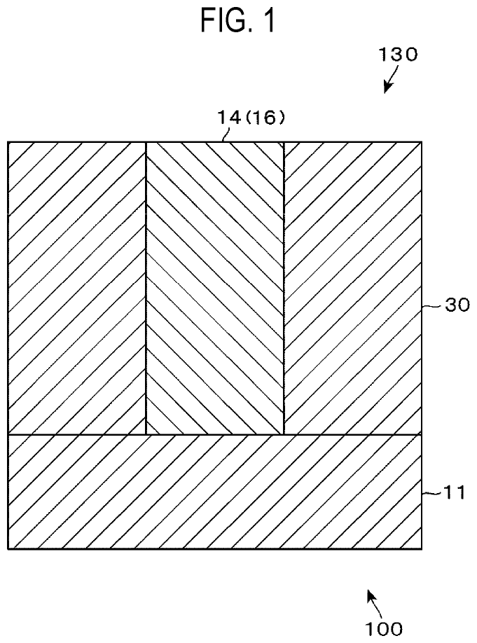

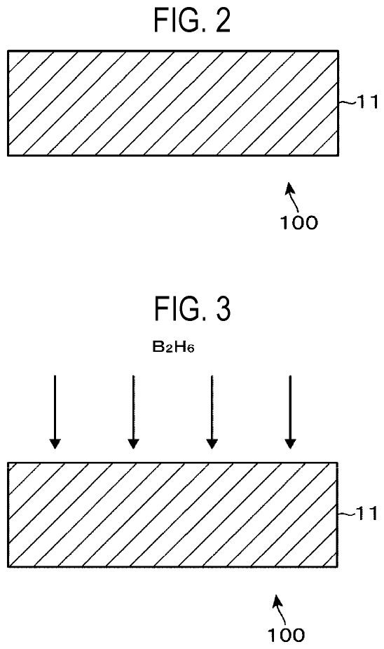

An embodiment of a method of manufacturing a semiconductor device according to the present disclosure will be described. In this embodiment, as illustrated in FIG. 1, a processing of forming a buried region 130, in which ruthenium (Ru) is buried in a via hole of an SiO₂ film 30 stacked on a cobalt (Co) film 11, as an example of a conductive film formed on a surface of a wafer 100 will be described. Since this processing may be understood as a processing of stacking an Ru film 14 (or an Ru film 16 according to a comparative embodiment to be described later) on the Co film 11 exposed inside the via hole, FIGS. 2 to 7 to be described later focus on and illustrate the Co film 11, the Ru film 14, and the Ru film 16 in brief.

### <Problems in Processing of Stacking Ru Film on Co Film>

Before describing a specific method of manufacturing a semiconductor device, problems in a case of directly stacking the Ru film on the Co film will be described.

If the Ru film is stacked so as to directly come into contact with the Co film, interfacial diffusion occurs between the Co film and the Ru film when the wafer 100 is heated to a high temperature upon subsequent annealing. That is, metal atoms constituting the Co film and the Ru film move from one side to the other side. Thereby, an alloy of Co and Ru is created at a contact portion of the Co film and the Ru film, which increases an electrical resistance between the Co film and the Ru film.

Therefore, in the present embodiment, an Ru film 13 including boron (B) of B₂H₆ is formed on the Co film 11 (FIG. 2) in order to prevent the creation of the alloy due to the interfacial diffusion. Here, it is understood that the Ru film 13 including B is more amorphous than an Ru film 15 including no B. As a result, it is considered that formation of gaps between atoms is prevented, which increases a barrier property against diffusion of Co.

The following method may be assumed as an example (comparative embodiment) of a method of forming the Ru film 13 including B on the Co film 11 using the above-described method.

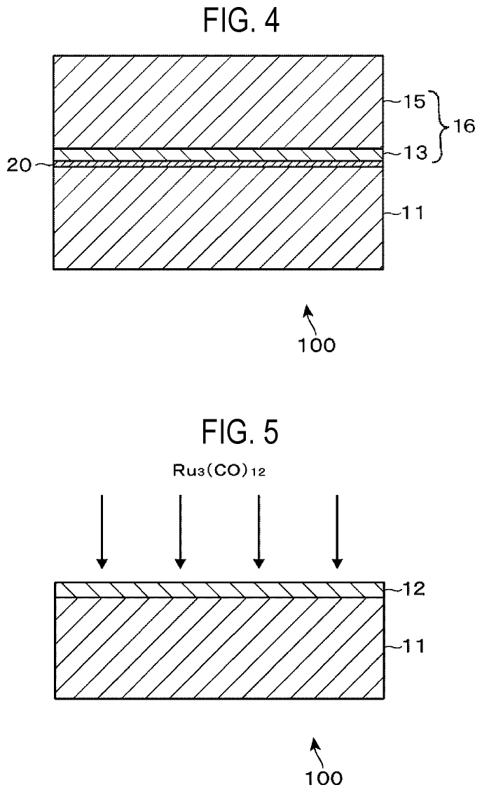

First, a diborane (B₂H₆) gas is supplied to the wafer 100 with the Co film 11 being exposed as illustrated in FIG. 2, such that the B₂H₆ gas is adsorbed onto the surface of the Co film 11 (FIG. 3). Subsequently, the supply of the B₂H₆ gas is stopped, and a ruthenium raw material gas, for example, a dodecacarbonium triruthenium (Ru₃(CO)₁₂) gas is supplied to the wafer 100 to perform chemical vapor deposition (CVD). Thereby, the Ru film 13 including B may be formed on the Co film 11. Also subsequently, the Ru film 15 may be formed on the Ru film 13 including B by supplying the Ru₃(CO)₁₂ gas (FIG. 4). The Ru film 16 in FIG. 4 refers to a stacked film in which the Ru film 15 is formed on the Ru film 13 including B.

However, it was found that, when employing a method of exposing the Co film 11 to the B₂H₆ gas, and then supplying the Ru₃(CO)₁₂ gas, an oxide layer 20 of B is formed at an interface between the Co film 11 and the Ru film 13 including B, as illustrated in Comparative Example 1 to be described later. If such an oxide layer 20 is formed, an electrical resistance between the Ru film 13 and the Co film 11 will increase.

Therefore, the inventors studied the cause of the formation of the oxide layer 20 of B. Oxygen (O) adhering to a surface of the Co film 11, oxygen included in the Co film 11, and oxygen included in the Ru₃(CO)₁₂ gas are conceivable as the origin of oxygen forming the oxide layer 20. Further, a small amount of oxygen in the air passing through an O-ring that serves to airtightly keep a processing space for the wafer 100, or the like is conceivable as the origin of the oxygen forming the oxide layer 20. The inventors presumed whether the oxide layer 20 of B is produced by a reaction of such oxygen with B.

As described above, in the method described with reference to FIGS. 2 to 4, it was found that an oxide of B is formed on the surface of the Co film 11 by supplying the B₂H₆ gas so as to be brought into contact with the Co film 11. Furthermore, it was known that when the Ru film 15 is formed thereafter, the oxide layer 20 of B remains at an interface between the Ru film 16 (the Ru film 13 including B) and the Co film 11.

### <Embodiment of Method of Manufacturing Semiconductor Device>

Therefore, in an embodiment of a method of manufacturing a semiconductor device according to the present disclosure, in order to prevent the formation of such an oxide layer 20 of B, the Ru film 14 is formed on the Co film 11 by alternately repeating formation of an Ru thin film on the surface of the Co film 11, and then the supply of the B₂H₆ gas a plurality of times.

Hereinafter, each processing performed on the wafer 100 will be described with reference to FIGS. 2, 5, 6, and 7. The processing illustrated in these drawings is performed in a state where the wafer 100 is stored in a processing container and is heated to a preset temperature, and the interior of the processing container is under a vacuum atmosphere. The Co film 11 formed by, for example, physical vapor deposition (PVD) is exposed on the surface of the wafer 100 illustrated in FIG. 2.

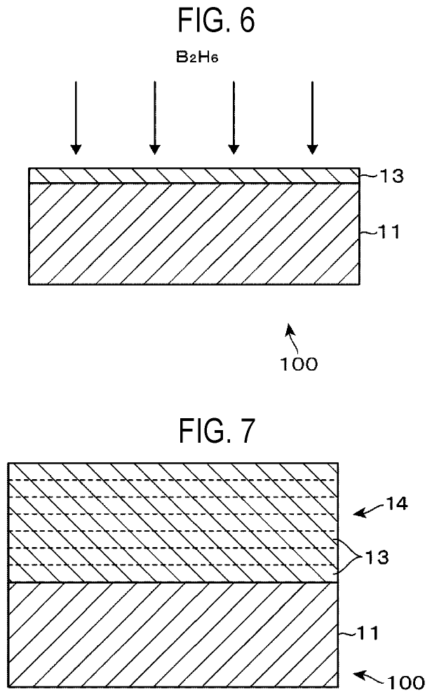

First, for example, the Ru₃(CO)₁₂ gas is supplied to the wafer 100 to form an Ru thin film 12 by chemical vapor deposition (CVD) (FIG. 5). Next, the supply of the Ru₃(CO)₁₂ gas is stopped, and the B₂H₆ gas is applied to the wafer 100 (FIG. 6). By this processing, the Ru film 13 including B may be formed on the surface of the Co film 11. Then, the formation of the Ru thin film 12 illustrated in FIG. 5 and the supply of the B₂H₆ gas illustrated in FIG. 6 are alternately repeated a plurality of times to stack the Ru film 13 including B (FIG. 7). Thus, the Ru film 14 (more precisely, a film obtained by stacking the Ru film 13 including B) may be formed on the Co film 11.

By first forming the Ru thin film 12 and supplying the B₂H₆ gas to the Ru thin film 12 as described above, the Ru film 13 including B is formed while preventing contact between the Co film 11 and the B₂H₆ gas. As a result, it is possible to prevent the oxide layer 20 of B from being formed on the surface of the Co film 11. The following examples to be described later illustrate that the formation of the oxide layer 20 of B at an interface between the Co film 11 and the Ru film 14 may be prevented by applying the method of manufacturing the semiconductor device according to the present disclosure.

In a subsequent processing operation, the wafer 100 is subjected to annealing under an N₂ gas atmosphere as a heat treatment. At this time, the aforementioned interfacial diffusion is prevented since the Ru film 14 includes B. That is, migration of Co constituting the Co film 11 to the Ru film 14 and migration of Ru constituting the Ru film 14 to the Co film 11 are inhibited, respectively. As a result, the formation of the alloy of Co and Ru is prevented.

By preventing the formation of the oxide layer 20 of B at the interface between the Co film 11 and the Ru film 14 and also by preventing the formation of the alloy of Ru and Co, it is possible to prevent an increase in the electrical resistance between the Co film 11 and the Ru film 14.

Further, with regard to supplying the B₂H₆ Gas and the Ru₃(CO)₁₂ gas, if both gases are simultaneously supplied to the wafer 100, the Ru film 14 is less likely to become amorphous. Therefore, there is a risk that the migration of Co to the Ru film 14 and the migration of Ru constituting the Ru film 14 to the Co film 11 may easily occur due to a low barrier property. Thus, the B₂H₆ gas and the Ru₃(CO)₁₂ gas may be alternately supplied by switching, rather than being supplied at the same time.

Further, if the thickness of the Ru thin film 12 formed at once becomes thick during alternately performing the formation of the Ru thin film 12 and the supply of the B₂H₆ gas as already described, B may not completely diffuse to an underlayer of the Ru thin film 12 when the B₂H₆ gas is supplied. If such a layer including no B or a layer including little B is formed, Co diffuses to the Ru film 14 or Ru diffuses to the Co film 11 when annealing is performed. Further, if the Ru thin film 12 is too thin, there is a risk that the number of repetitions increases, causing a reduced throughput. Therefore, the thickness of the Ru thin film 12 formed at once may be 0.268 nm or more and 2 nm or less. The lower limit of the thickness, 0.268 nm, is twice an atomic radius of Ru, 0.134 nm.

Further, in order to reliably prevent the formation of the oxide layer 20 of B, the Ru film 14 formed by stacking the Ru film 13 including B may have a film thickness of 2 nm or more, for example. This is because the Ru film 14 becomes a continuous film when having the film thickness of 2 nm or more. Further, when forming the Ru film 14 having a certain target film thickness, a film thickness of a stacked film portion in which two or more layers of the Ru film 13 including B are stacked may be less than the target film thickness. The Ru film 14 having the target film thickness may be formed by forming the stacked film in which the two or more layers of the Ru film 13 including B are stacked, and then forming an Ru film including no B on the stacked film.

Further, the Co film 11 may be formed by any method of PVD and CVD. Further, the Ru thin film 12 is also not limited to being formed by CVD, and may be formed by, for example, PVD.

In a case of the configuration described with reference to FIG. 1, both the Co film 11 and the Ru film 14 are films constituting a wiring of a semiconductor device. In addition, the Co film 11 may be a barrier film that is formed along a via hole formed in an insulating film (SiO₂ film 30) to prevent Ru atoms from diffusing to the insulating film when the Ru film 14 serving as the wiring is buried in the via hole.

Further, a ruthenium raw material gas for forming the Ru film 14 may be, for example, (2,4-dimethylpentadienyl)(ethylcyclopentadienyl)ruthenium: (Ru(DMPD)(EtCp)), bis(2,4-dimethylpentadienyl)Ruthenium: (Ru(DMPD)₂), 4-dimethylpentadienyl)(methylcyclopentadienyl)Ruthenium: (Ru(DMPD)(MeCp)), Bis(Cyclopentadienyl)Ruthenium: (Ru(C₅H₅)₂), Cis-dicarbonyl bis(5-methylhexane-2,4-dionate) ruthenium (II), bis (ethylcyclopentadienyl)Ruthenium(II): Ru(EtCp)₂, or the like.

Further, a boron compound gas supplied to make the Ru thin film 12 include B may be any gas including boron (B), and is not limited to the B₂H₆ gas. For example, a gas including B such as monoborane, trimethylborane, triethylborane, dicarbadodecaborane, and decaborane may be used.

### <Film Forming Apparatus>

Subsequently, a film forming apparatus 41 for the Ru film 14 capable of performing the processing described in the above-described embodiment will be described. The film forming apparatus 41 corresponds to an embodiment of an apparatus of manufacturing a semiconductor device according to the present disclosure.

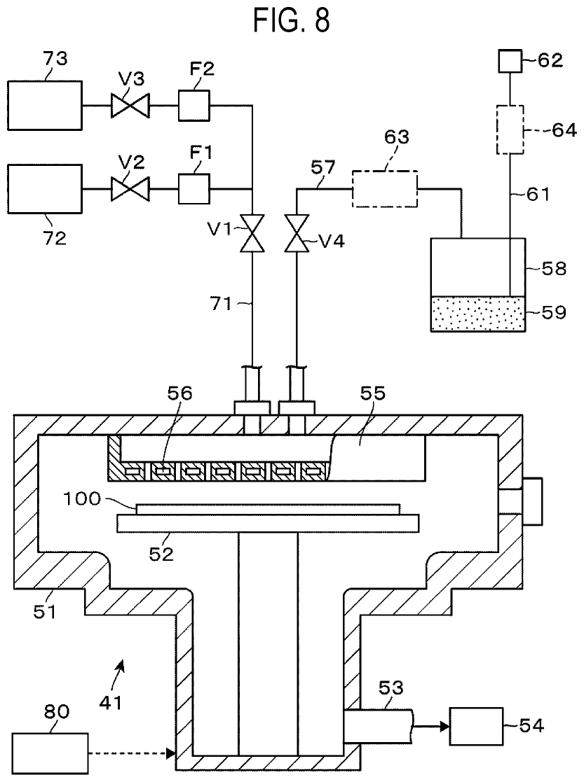

As illustrated in FIG. 8, the film forming apparatus 41 includes a processing container 51, and a stage 52 in which a heater is embedded is provided inside the processing container 51. The wafer 100 is transferred between the top of the stage 52 and an external transfer mechanism (not illustrated) via a lifting pin (not illustrated) provided on the stage 52. An upstream end of an exhaust pipe 53 is open to the processing container 51, and a downstream side of the exhaust pipe 53 is connected to a vacuum exhaust mechanism 54 for exhausting the interior of the processing container 51 to create a vacuum atmosphere.

A gas shower head 55 is provided in an upper portion inside the processing container 51. Reference numeral 56 in FIG. 8 indicates a flow path for a temperature adjustment fluid provided in the gas shower head 55. A downstream end of a gas supply path 57 is connected to the gas shower head 55, and a raw material bottle 58 is connected to a proximal end side of the gas supply path 57. The raw material bottle 58 accommodates, for example, Ru₃(CO)₁₂ powder 59. Further, a downstream end of a gas supply path 61 is open in the raw material bottle 58, and an upstream end of the gas supply path 61 is connected to a source 62 of a carbon monoxide (CO) gas which is a carrier gas. Reference numerals 63 and 64 in FIG. 8 indicate gas supply equipment groups interposed respectively in the gas supply paths 57 and 61. For example, the gas supply equipment groups 63 and 64 each include a valve and a flow rate regulator. In addition, reference numeral V4 in FIG. 8 indicates a valve interposed in the gas supply path 57. The gas supply path 57, the raw material bottle 58, the gas supply path 61, the CO gas source 62, the gas supply equipment groups 63 and 64, and the valve V4 correspond to a ruthenium raw material gas supplier.

In the above-described configuration, when the carrier gas is supplied to the raw material bottle 58, the Ru₃(CO)₁₂ is sublimated, and this Ru₃(CO)₁₂ gas is supplied to the gas shower head 55 together with the carrier gas.

Further, a gas supply path 71 is connected to the gas shower head. A proximal end side of the gas supply path 71 is branched, and is connected to a B₂H₆ gas source 72 and a source 73 for a carrier gas such as nitrogen (N₂). Reference numerals V1 to V3 in FIG. 8 indicate valves interposed in the gas supply path 71. Further, reference numerals F1 and F2 in FIG. 8 indicate flow rate regulators interposed in the gas supply path 71. The gas supply path 71, the B₂H₆ gas source 72, the carrier gas source 73, the valves V1 to V3, and the flow rate regulators F1 and F2 correspond to a boron compound gas supplier.

The film forming apparatus 41 includes a controller 80 (see FIG. 8) which is a computer, and this controller 80 operates based on a program. This program is stored in a storage medium such as, for example, a compact disc, hard disc, magneto-optical disc, or DVD, and is installed in the controller 80. The controller 80 controls operations such as the supply/stop of each gas to the wafer 100 in the film forming apparatus 41 and the heating of the wafer 100 by the program. Then, a group of steps is organized so that a series of processing described with reference to FIGS. 2 and 5 to 7 may be performed by the program.

When the wafer 100 is processed as described above, the wafer 100 placed on the stage 52 of the film forming apparatus 41 is heated to, for example, 100 degrees C. to 250 degrees C., and an internal pressure of the processing container 51 is adjusted to, for example, 1.33 Pa (10 mTorr) to 13.3 Pa (100 mTorr). After the adjustment of the temperature and the pressure, the Ru₃(CO)₁₂ gas is supplied into the processing container 51 through the raw material bottle 58 at, for example, 100 sccm to 600 sccm, more specifically, for example, 300 sccm for 10 to 70 seconds, so that the Ru thin film 12 is formed. In addition, the supply time of the Ru₃(CO)₁₂ gas depends on the pressure and is about 30 seconds at 66.5 Pa (50 mTorr) and about 10 seconds at 22.2 Pa (16.6 mTorr).

Next, the B₂H₆ gas is supplied into the processing container 51 at, for example, 100 sccm to 2,000 sccm, and the N₂ gas is supplied at, for example, 0 sccm to 1,000 sccm for the implementation of a processing. The supply time of these B₂H₆ gas and N₂ gas is, for example, 10 seconds to 300 seconds. Then, the formation of the Ru thin film 12 and the supply of the B₂H₆ gas are alternately repeated a plurality of times, so that the Ru film 14 is formed.

<Example of Annealing after Formation of Ru Film>

In addition, an example of a processing condition upon annealing performed after the formation of the Ru film 14 is illustrated. For example, annealing sets the interior of the processing container 51 to an N₂ atmosphere and to 133 Pa to 931 Pa (1 Torr to 7 Torr), more specifically, for example, to 667 Pa (5 Torr). In this pressure state, the wafer 100 is heated at, for example, 300 degrees C. to 500 degrees C. The heating of the wafer 100 is performed, for example, by the heater of the stage on which the wafer 100 is placed, similarly to a case where the wafer 100 is heated in each film forming apparatus 41.

### <Another Example of Conductive Film>

A conductive film formed on the wafer 100 on which the Ru film 14 is formed using the method of manufacturing the semiconductor device and the film forming apparatus of the present disclosure is not limited to the example of the Co film 11 already described above. A technology of the present disclosure may be applied to any other conductive film as long as it includes a metal that increases an electrical resistance between the conductive film and the Ru film 15 by interfacial diffusion between the conductive film and the Ru film 15. A Ti film including titanium (Ti) or an Ni film including nickel (Ni) may be exemplified as such a conductive film.

### Other Applications

In addition, it should be noted that the embodiments disclosed herein are exemplary in all respects and are not restrictive. The above-described embodiments may be omitted, replaced, modified, or combined in various forms without departing from the scope and spirit of the appended claims.

### EXAMPLES

An experiment was conducted in order to verify the effects of the method of manufacturing the semiconductor device according to the present disclosure.

### Example 1

Example 1 is an example in which the Co film 11 is formed on the wafer 100 on which a silicon oxide (SiO₂) is formed, and the Ru film 14 is formed on the surface of the Co film 11 according to the method of manufacturing the semiconductor device according to an embodiment.

### Comparative Example 1

Comparative Example 1 is an example in which, after the Co film 11 is formed on the same wafer 100 and then the B₂H₆ gas is supplied, the Ru₃(CO)₁₂ is continuously supplied to the wafer 100 to form the Ru film 16 (the Ru film 13 including B and the Ru film 15 illustrated in FIG. 4).

### Comparative Example 2

Comparative Example 2 is an example in which the Co film 11 is formed on the same wafer 100, and then the Ru₃(CO)₁₂ is supplied to the wafer 100 to form the Ru film without performing the supply of the B₂H₆ gas.

For Example 1 and Comparative Example 1, atomic distribution in a depth direction from the surface of the wafer 100 was measured by energy dispersive X-ray spectroscopy (SEM EDX).

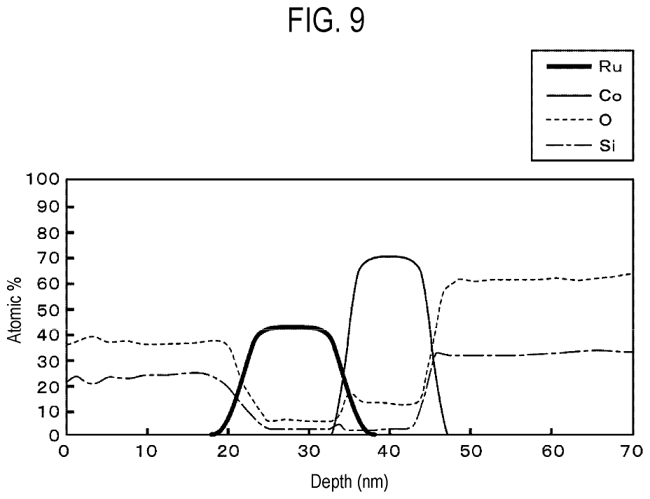

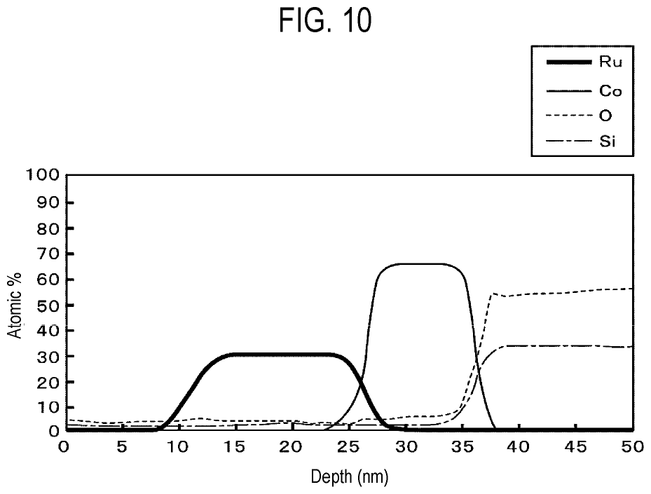

FIGS. 9 and 10 show results of Comparative Example 1 and Example 1, respectively, and show content ratios (atomic %) of Co, Ru, 0, and Si with respect to the depth direction of the wafer 100.

As illustrated in FIG. 9, in Comparative Example 1, a layer including a large amount of Ru in a depth range of 20 nm to 35 nm was detected, and a layer including a large amount of Co in a depth range of 35 nm to 45 nm was detected. Then, an oxygen peak was detected between the Ru layer and the Co layer.

Further, as illustrated in FIG. 10, in Example 1, a layer including a large amount of Ru in a depth range of 10 nm to 25 nm was detected, and a layer including a large amount of Co in a depth range of 25 nm to 35 nm was detected. On the other hand, no oxygen peak was detected between the Ru layer and the Co layer.

In this regard, it can be said that in Comparative Example 1, an oxide (oxide layer 20 illustrated in FIG. 4) was formed between the Ru layer and the Co layer (between the Co film 11 and the Ru film 15 illustrated in FIG. 4), whereas in Example 1, the formation of the oxide layer 20 may be prevented.

Further, for Example 1 and Comparative Example 2, annealing was performed, and atomic distribution in the depth direction of the wafer 100 before and after annealing was measured by secondary ion mass spectrometry (SIMS).

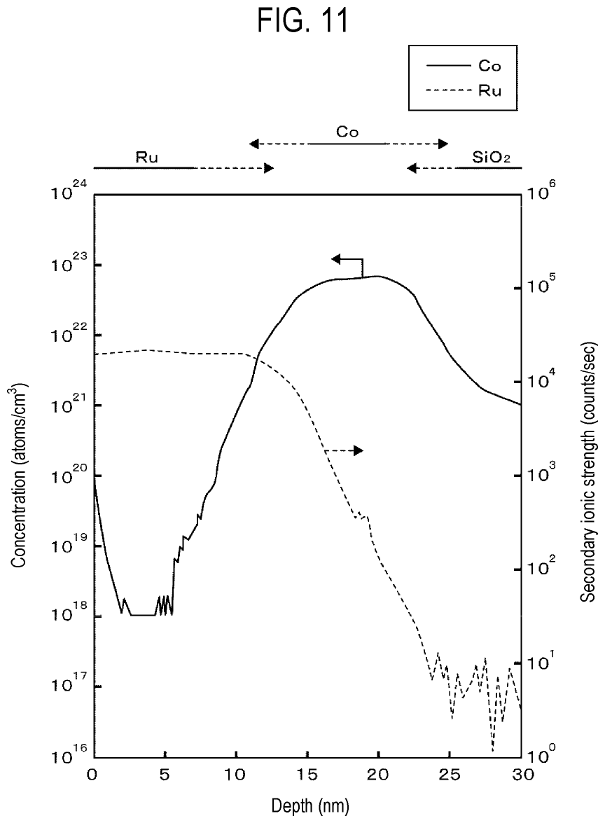

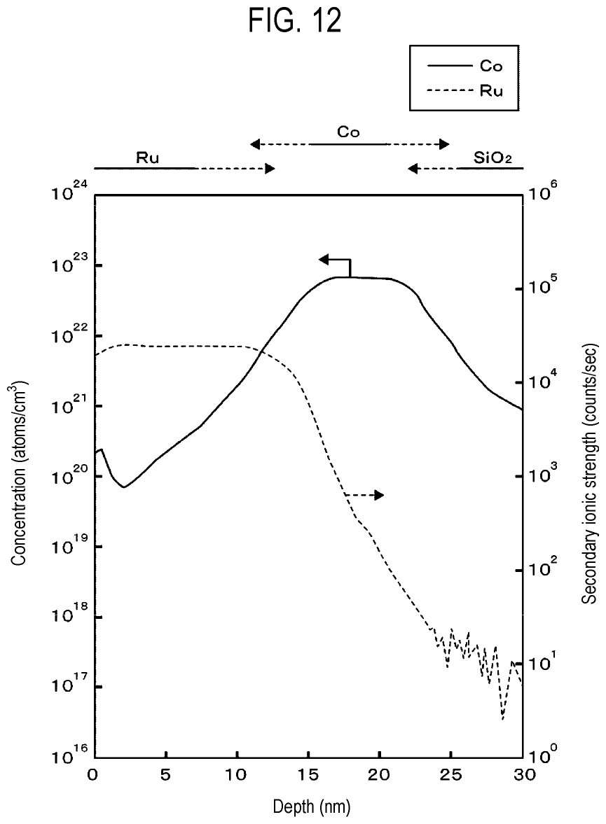

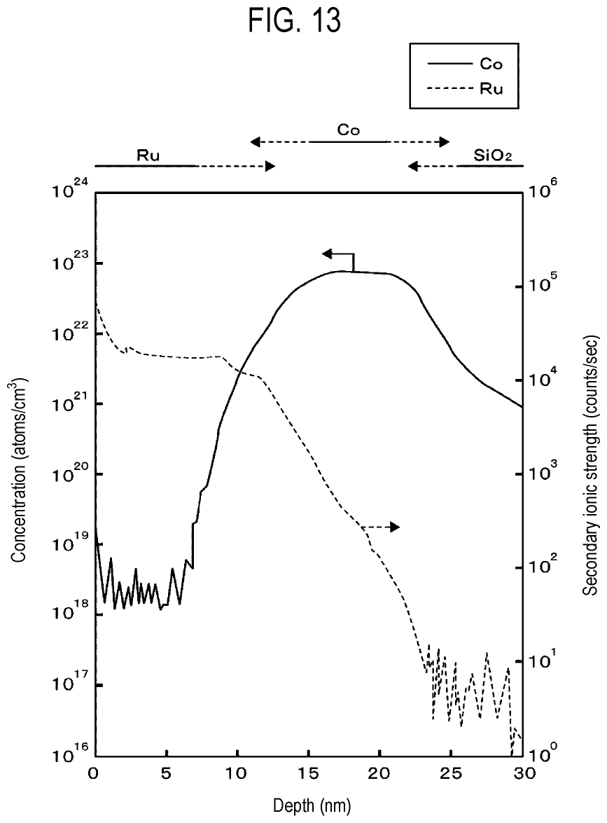

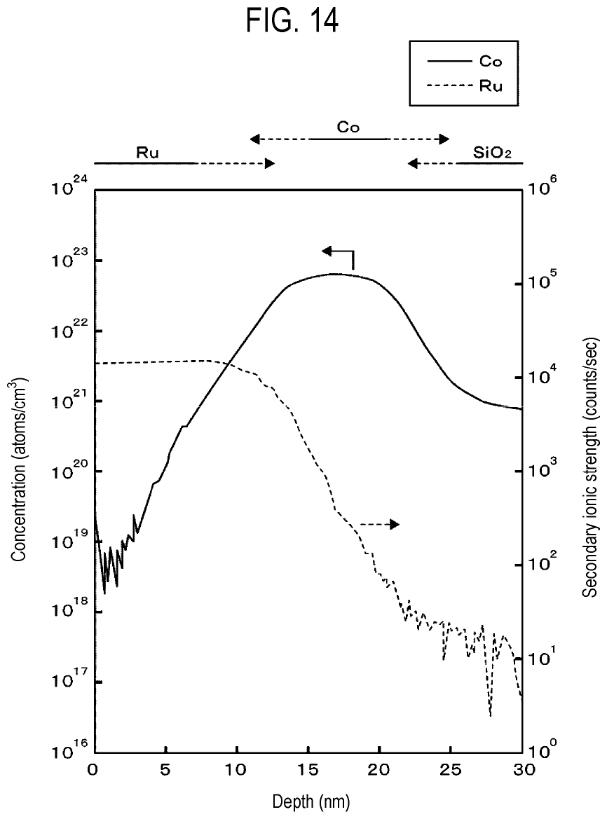

FIG. 11 illustrates distribution of Co and Ru before annealing in Comparative Example 2. FIG. 12 illustrates distribution of Co and Ru after annealing in Comparative Example 2. FIG. 13 illustrates distribution of Co and Ru before annealing in Example 1. FIG. 14 illustrates distribution of Co and Ru after annealing in Example 1.

As illustrated in FIGS. 11 and 13, in both Example 1 and Comparative Example 2, a content of Co in a region corresponding to the Ru film 14 is low before annealing. However, in Comparative Example 2, after annealing, the content of Co in a region close to the surface was increased as illustrated in FIG. 12. On the other hand, in Example 1 illustrated in FIG. 14, even after annealing, the content of Co in the region corresponding to the Ru film 14 was reduced to a low concentration as compared with Comparative Example 2 in FIG. 12.

This is conceivable because Co diffuses into the Ru film in Comparative Example 2, but the diffusion of Co into the Ru film 14 may be prevented in Example 1. Accordingly, in Example 1 in which the Ru film 14 was formed by alternately repeating the formation of the Ru thin film and the supply of the B₂H₆ gas a plurality of times, it can be said that the diffusion of Co into the Ru film 14 may be prevented, which may prevent an increase in an electrical resistance of the Ru film 14.

### EXPLANATION OF REFERENCE NUMERALS

11: Co film, 12: Ru thin film, 13: Ru film including boron, 14: Ru film, 15: Ru film, 16: Ru film, 20: oxide layer, 30: SiO₂ film, 100: wafer, 41: film forming apparatus, 51: processing container, 52: stage, 53: exhaust pipe, 54: vacuum exhaust mechanism, 55: gas shower head, 56: flow path, 57: gas supply path, 58: raw material bottle, 59: powder, 61: gas supply path, 62: carbon monoxide gas source, 63: gas supply equipment group, 64: gas supply equipment group, 71: gas supply path, 72: B₂H₆ gas source, 73: carrier gas source, 80: controller, F1: flow rate regulator, F2: flow rate regulator, V1: valve, V2: valve, V3: valve, V4: valve

1-9. (canceled)

10. A method for manufacturing a semiconductor device that includes forming a ruthenium film on a conductive film formed on a substrate for manufacture of the semiconductor device,
wherein the conductive film includes a metal that increases an electrical resistance between the conductive film and the ruthenium film by interfacial diffusion between the conductive film and the ruthenium film, and
wherein the method comprises forming the ruthenium film on the conductive film by alternately repeating a plurality of times:
forming a ruthenium thin film by supplying a ruthenium raw material gas to the substrate on which the conductive film is formed; and
then supplying a boron compound gas to the ruthenium thin film.

11. The method of claim 10, wherein the conductive film is a cobalt film including cobalt.

12. The method of claim 11, wherein the boron compound gas is a diborane gas.

13. The method of claim 12, wherein the ruthenium raw material gas is a dodecacarbonium triruthenium gas.

14. The method of claim 13, wherein the ruthenium thin film has a film thickness of 0.268 nm or more and 2 nm or less.

15. The method of claim 10, wherein the boron compound gas is a diborane gas.

16. The method of claim 10, wherein the ruthenium raw material gas is a dodecacarbonium triruthenium gas.

17. The method of claim 10, wherein the ruthenium thin film has a film thickness of 0.268 nm or more and 2 nm or less.

18. An apparatus for manufacturing a semiconductor device that forms a ruthenium film on a conductive film formed on a substrate for manufacture of the semiconductor device, the apparatus comprising:
a processing container configured to accommodate the substrate on which the conductive film is formed, the conductive film including a metal that increases an electrical resistance between the conductive film and the ruthenium film by interfacial diffusion between the conductive film and the ruthenium film;
a ruthenium raw material gas supplier configured to supply a ruthenium raw material gas to the processing container;
a boron compound gas supplier configured to supply a boron compound gas to the processing container; and
a controller,
wherein the controller is configured to control the ruthenium raw material gas supplier and the boron compound gas supplier so as to form the ruthenium film on the conductive film by alternately repeating a plurality of times:
forming a ruthenium thin film by supplying the ruthenium raw material gas to the substrate on which the conductive film is formed; and
then supplying the boron compound gas to the ruthenium thin film.

19. The apparatus of claim 18, wherein the conductive film is a cobalt film including cobalt.

20. The apparatus of claim 19, wherein the boron compound gas is a diborane gas.

21. The apparatus of claim 20, wherein the ruthenium raw material gas is a dodecacarbonium triruthenium gas.

22. The apparatus of claim 18, wherein the boron compound gas is a diborane gas.

23. The apparatus of claim 18, wherein the ruthenium raw material gas is a dodecacarbonium triruthenium gas.
